(19) United States
(12) Patent Application Publication
(10) Pub. No.: US 2017/0166786 A1
(43) Pub. Date: Jun. 15, 2017

(54) ADHESIVE SHEET AND OPTICAL DISPLAY COMPRISING THE SAME

(71) Applicants: SAMSUNG SDI CO., LTD., Yongin-si (KR); SAMSUNG ELECTRONICS CO., LTD., Suwon-si (KR)

(72) Inventors: Hyung Rang Moon, Suwon-si (KR); Chung Kun Cho, Yongin-si (KR); Mikhail Kovalev, Suwon-si (KR); Fedosya Kalinina, Suwon-si (KR)

(21) Appl. No.: 15/372,226

(22) Filed: Dec. 7, 2016

(30) Foreign Application Priority Data
Dec. 11, 2015 (KR) 10-2015-0177499

(51) Int. Cl. C09J 133/06; H01L 51/00; H01L 51/52; C09J 11/06

(52) U.S. Cl. CPC C09J 133/066; C09J 11/06; H01L 51/004; H01L 51/0043; H01L 51/5246; H01L 51/5281

(57) ABSTRACT

An adhesive sheet and an optical display including the same are provided. An adhesive sheet includes an adhesive film including: a first region; and a second region coplanar with the first region and having a higher modulus than the first region.

### CROSS-REFERENCE TO RELATED APPLICATION

This application claims priority to and the benefit of Korean Patent Application No. 10-2015-0177499, filed on Dec. 11, 2015 in the Korean Intellectual Property Office, the entire content of which is incorporated herein by reference.

### BACKGROUND

1. Field

Aspects of embodiments of the present invention relate to an adhesive sheet and an optical display including the same.

2. Description of the Related Art

An optical display includes a window film, a conductive film, a panel including an organic light emitting device, and a display device including an adhesive film and the like. Recently, flexible optical displays are developed as optical displays.

Display devices of a flexible optical display need to have flexibility.

Therefore, a window film is formed of a flexible material instead of hard tempered glass. However, when a flexible optical display including a window film formed of a flexible material receives external impact, an organic light emitting device panel can be easily damaged. To solve this problem, when an adhesive film used to bond an organic light emitting device panel to other display devices has high modulus, the adhesive film can suffer from damage or detachment at a bending portion thereof upon repeated folding at low temperature, thereby causing deterioration in reliability of the flexible optical display.

The background technique of the present invention is disclosed in Korean Patent Publication No. 2007-0055363 A.

### SUMMARY

In accordance with an aspect of one or more embodiments of the present invention, an adhesive sheet may include an adhesive film including: a first region; and a second region coplanar with the first region and having a higher modulus than the first region.

In accordance with another aspect of one or more embodiments of the present invention, an optical display may include the adhesive sheet according to an embodiment of the present invention.

In an embodiment, the optical display may further include a window film; and an organic light emitting device panel, and the adhesive sheet may be arranged on a lower surface of the organic light emitting device panel.

### BRIEF DESCRIPTION OF DRAWINGS

FIG. 1 is a perspective view of an adhesive sheet according to an embodiment of the present invention.

FIG. 2 is a perspective view of an adhesive sheet according to another embodiment of the present invention.

FIG. 3 is a perspective view of an adhesive sheet according to another embodiment of the present invention.

FIG. 4 is a cross-sectional view of a flexible optical display according to an embodiment of the present invention.

FIG. 5 is a cross-sectional view of a flexible optical display according to another embodiment of the present invention.

FIG. 6 is a cross-sectional view of a flexible optical display according to another embodiment of the present invention.

### DETAILED DESCRIPTION

Some embodiments of the present invention will be described in further detail with reference to the accompanying drawings. It should be understood that the present invention may be embodied in different ways and is not limited to the following embodiments. In the drawings, portions irrelevant to the description will be omitted for clarity. Like components will be denoted by like reference numerals throughout the specification.

As used herein, spatially relative terms such as “upper” and “lower” are defined with reference to the accompanying drawings. Thus, it will be understood that “upper surface” can be used interchangeably with “lower surface.” It will be understood that when an element such as a layer, a film, a region, or a substrate is referred to as being placed “on” another element, it can be directly placed on the other element, or intervening layer(s) may be present. When an element is referred to as being directly placed “on” another element, intervening layer(s) are not present.

As used herein, the term “(meth)acryl” refers to acryl and/or methacryl.

As used herein, the term “modulus” refers to storage modulus, as measured on a specimen having a size of 10 mm×10 mm (width×length) and attached to both sides of a central substrate. The specimen is prepared by stacking an adhesive film to a thickness of 600 μm and the modulus of the specimen is measured by measuring viscoelasticity under conditions of a frequency of 1 Hz and a shear strain of 2% (displacement: 16 μm) in a shear strain mode using a dynamic viscoelasticity instrument DMA/SDTA861 (Mettler Co., Ltd.) while increasing the temperature of −60° C. to 100° C. at a rate of 5° C./min. Herein, the moduli of the specimen at −20° C., 25° C. or 80° C. is measured.

Herein, “foldability evaluation” of an adhesive film is carried out on a specimen in the following manner. An adhesive film is placed between a corona-treated polyethylene terephthalate (PET) film (thickness: 125 μm) and a corona-treated PET film (thickness: 50 μm) and bonded to the PET films through rollers, followed by aging at room temperature for 12 hours. Next, the resultant is cut to a size of 70 mm×140 mm (width×length), thereby preparing a specimen. In evaluation of foldability, the specimen is secured to a flexibility evaluation instrument CFT-200 (Covotech Co., Ltd.) using an adhesive (4965, Tesa Co., Ltd.) and folding is performed at −20° C. or 60° C. and 93% relative humidity at a folding frequency of 30 cycles/min under the condition of a holding time of 0.1 seconds after each folding such that the radius of curvature becomes 3 mm (1 cycle being defined as an operation of folding the specimen in half once and unfolding the specimen). A bending portion of the adhesive film is a first region of the adhesive film.

Herein, “number of folding cycles” of an adhesive film refers to the number of cycles which causes striped pattern, breakage, detachment, peeling or the like in a folding portion of the adhesive film for the first time, where 1 cycle is defined as an operation of folding the adhesive film once upon foldability evaluation as set forth above. A higher number of folding cycles of an adhesive film means that the adhesive film exhibits better foldability and is suitable for use in flexible displays.

Herein, “good foldability” means that a number of folding cycles causing breakage, detachment, or peeling of an adhesive film is greater than about 100,000 cycles or more upon foldability evaluation as set forth above.

Herein, the “average particle diameter” of organic nanoparticles refers to a z-average particle diameter of the organic nanoparticles, as measured in a water-based or organic solvent using a Zetasizer nano-ZS (Malvern Co., Ltd.).

An adhesive sheet according to an embodiment of the present invention will be described in further detail.

According to an embodiment of the present invention, an adhesive sheet may include an adhesive film, which includes: a first region; and at least one region coplanar with the first region and having a higher modulus than the first region. The adhesive film may be composed of a single layer. Thus, the adhesive sheet concurrently (e.g., simultaneously) includes at least two regions having different moduli on the same plane and in a single layer, thereby improving applicability of the adhesive sheet.

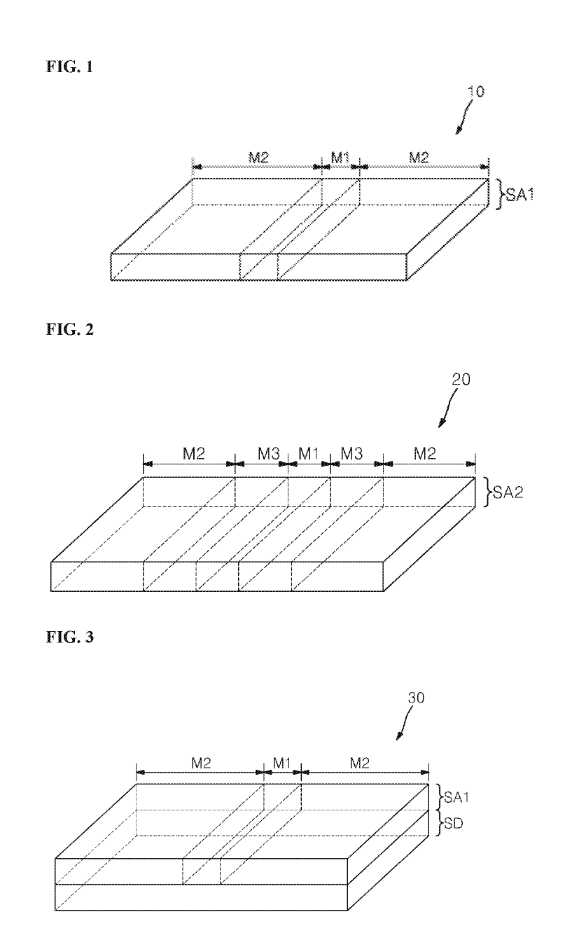

An adhesive sheet according to an embodiment of the present invention will be described with reference to FIG. 1. FIG. 1 is a perspective view of an adhesive sheet according to an embodiment of the present invention.

Referring to FIG. 1, an adhesive sheet 10 according to an embodiment may include an adhesive film SA1 including a first region M1 and second regions M2, in which the second regions M2 may be coplanar with the first region M1 and have higher modulus than the first region M1. The first region M1 is formed between a second region M2 and an adjacent second region M2, and the first region M1 and the second regions M2 are formed as one body. As used herein, the expression “being formed as one body” means that the first and second regions are concurrently (e.g., simultaneously) formed by coating the same adhesive composition once instead of being separately formed and bonded to each other via a bonding agent or an adhesive. Therefore, although the adhesive sheet according to this embodiment is composed of a single layer, the adhesive sheet can simultaneously have effects due to the first region having a lower modulus and the second regions having a higher modulus. For example, the adhesive sheet may be used for a flexible display. The first region M1 forms a bending region due to low modulus thereof, thereby allowing the adhesive sheet to exhibit good foldability. The second regions M2 form non-bending regions due to high modulus thereof, and thus improve impact resistance of a display device, for example, an organic light emitting device, or an organic light emitting device-containing panel by preventing or substantially preventing external impact on the display device, thereby preventing or substantially preventing damage to the display device.

A modulus ratio of the second regions M2 to the first region M1 (that is, modulus of the second regions M2/modulus of the first region M1) at each of −20° C. and 25° C. may be greater than 1, and, in an embodiment, from about 1.1 to about 12, from about 1.1 to about 11, from about 1.1 to about 10, from about 1.1 to about 9, from about 1.1 to about 8, from about 1.1 to about 7, or from about 1.1 to about 6, and, in one embodiment, from about 1.1 to about 5. Within this range, the first region M1 corresponding to a bending region has excellent flexural properties, and the second regions M2 have touch functionality and impact resistance, thereby satisfying two merits of a flexible display.

The first region M1 may have a modulus at −20° C. of about 0.1 MPa to about 10 MPa, and, in an embodiment, about 0.1 MPa to about 6 MPa, about 0.1 MPa to about 5 MPa, about 0.1 MPa to about 4 MPa, about 0.2 MPa to about 4 MPa, or about 0.2 MPa to about 3.5 MPa. The second regions M2 may have a modulus at −20° C. of about 1 MPa to about 20 MPa, and, in an embodiment, about 1.5 MPa to about 15 MPa, about 1.5 MPa to about 14 MPa, about 1.5 MPa to about 13 MPa, or about 1.5 MPa to about 12 MPa. Within this range, the adhesive film can be prevented or substantially prevented from being broken when folded at low temperature, and can exhibit excellent foldability.

The first region M1 may have a modulus at 25° C. of about 0.01 MPa to about 3 MPa, and, in an embodiment, about 0.1 MPa to about 1 MPa, or about 0.1 MPa to about 0.5 MPa. The second regions M2 may have a modulus at 25° C. of about 0.1 MPa to about 5 MPa, and, in an embodiment, about 0.2 MPa to about 3 MPa, about 0.2 MPa to about 2 MPa, or about 0.2 MPa to about 1 MPa. Within this range, the adhesive film can exhibit good foldability at room temperature, and the second regions M2 have impact resistance.

The first region M1 may have a modulus at 80° C. of about 0.01 MPa to about 2 MPa, and, in an embodiment, about 0.01 MPa to about 1 MPa; and the second regions M2 may have a modulus at 80° C. of about 0.01 MPa to about 3 MPa, and, in an embodiment, about 0.01 MPa to about 2 MPa. Within this range, the adhesive film can have improved peel strength at high temperature.

The first region M1 has a lower glass transition temperature than the second regions M2, thereby exhibiting excellent flexural properties even at lower temperature. A difference in glass transition temperature between the second regions M2 and the first region M1 may be in a range from about 2° C. to about 50° C., and, in an embodiment, from about 3° C. to about 50° C., and, in one embodiment, from about 3° C. to about 10° C., for example, about 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50° C.

The first region M1 may have a glass transition temperature of about −25° C. or less, and, in an embodiment, about −50° C. to about −25° C., about −45° C. to about −25° C., about −40° C. to about −25° C., or about −40° C. to about −29° C.; and the second regions M2 may have a glass transition temperature of about −20° C. or less, and, in an embodiment, about −40° C. to about −20° C., about −35° C. to about −20° C., or about −30° C. to about −20° C.

The first region M1 having a thickness of 30 μm may have a peel strength at 25° C. of about 400 gf/in or more, and, in an embodiment, about 400 gf/in to about 5,000 gf/in, or about 800 gf/in to about 3,000 gf/in, and, in one embodiment, about 850 gf/in to about 2,000 gf/in, and a peel strength at 60° C. of about 600 gf/in or more, and, in an embodiment, about 800 gf/in to about 5,000 gf/in, as measured with respect to a corona-treated PET film. Within this range, the first region M1 can exhibit good foldability and excellent reliability at high and low temperatures. The second regions M2 having a thickness of 30 μm may have a peel strength at 25° C. of about 800 gf/in or more, or about 800 gf/in to about 5,000 gf/in, and, in an embodiment, about 900 gf/in to about 3,000 gf/in, and, in one embodiment, about 1,000 gf/in to about 2,800 gf/in, or about 1,500 gf/in to about 2,800 gf/in, and a peel strength at 60° C. of about 700 gf/in or more, and, in an embodiment, about 800 gf/in to about 5,000 gf/in, as measured with respect to a corona-treated PET film. Within this range, the second regions M2 can have excellent adhesion and reliability at room temperature.

The adhesive film SA1 may have a thickness of about 200 μm or less, and, in an embodiment, about 15 μm to about 100 μm, or about 30 μm, or about 50 μm. Within this range, the adhesive film SA1 having a different thickness depending upon adherends can be variously used for an optical display and a display device can be protected from external impact.

The adhesive film SA1 may have a refractive index of about 1.40 to about 1.60, and, in an embodiment, about 1.45 to about 1.52. Within this range, the refractive index of the adhesive film SA1 matches that of an optical device, whereby the adhesive film SA1 can be used for an optical display.

The adhesive film SA1 may have a haze of about 1% or less, and, in an embodiment, about 0.1% to about 0.9%, and a total light transmittance of about 90% or more, and, in an embodiment, about 95% to about 99%, as measured in a visible spectrum (for example, at a wavelength of 380 nm to 780 nm). Within this range, the adhesive film SA1 can be used for an optical display due to good transparency thereof.

For the adhesive film SA1, an area ratio of the first region M1 to the second regions M2 may vary with an optical display for which the adhesive sheet 10 is used. For example, the area ratio of the first region M1 to the second regions M2 (area of the first region M1:area of the second regions M2) may be in a range from about 5:1 to about 1:20.

The adhesive film SA1, that is, the first region M1 and the second regions M2 may be formed of the same adhesive composition. Herein, an adhesive composition will be described in detail.

According to an embodiment of the invention, an adhesive composition may include a (meth)acrylic copolymer, a monofunctional (meth)acrylic monomer, a polyfunctional (meth)acrylic monomer, and an initiator.

The (meth)acrylic copolymer may form a matrix of an adhesive film.

The (meth)acrylic copolymer may be a copolymer of a monomer mixture including a hydroxyl group-containing (meth)acrylic monomer, an alkyl group-containing (meth)acrylic monomer, and a copolymerizable monomer.

The hydroxyl group-containing (meth)acrylic monomer improves adhesion of the adhesive film, and may include at least one of a hydroxyl group-containing (meth)acrylate, a hydroxyl group-containing (meth)acrylamide, and a hydroxyl group and alkylene glycol unit-containing (meth)acrylate. These hydroxyl group-containing (meth)acrylic monomers may be used alone or in combination thereof.

The hydroxyl group-containing (meth)acrylate may be a (meth)acrylate containing at least one hydroxyl group. For example, the hydroxyl group-containing (meth)acrylate may include at least one of 2-hydroxyethyl (meth)acrylate, 3-hydroxypropyl (meth)acrylate, 4-hydroxybutyl (meth)acrylate, hydroxyhexyl (meth)acrylate, 1,4-cyclohexanedimethanol mono(meth)acrylate, 1-chloro-2-hydroxypropyl (meth)acrylate, diethylene glycol mono(meth)acrylate, 1,6-hexanediol mono(meth)acrylate, pentaerythritol tri(meth)acrylate, dipentaerythritol penta(meth)acrylate, neopentyl glycol mono(meth)acrylate, trimethylolpropane di(meth)acrylate, trimethylolethane di(meth)acrylate, 2-hydroxy-3-phenyloxypropyl (meth)acrylate, 4-hydroxycyclopentyl (meth)acrylate, 4-hydroxycyclohexyl (meth)acrylate, and cyclohexanedimethanol mono(meth)acrylate. In this case, the adhesive film can be produced in high productivity and can exhibit further improved adhesion.

The hydroxyl group-containing (meth)acrylamide may include a (meth)acrylamide containing a C₁ to C₁₀ alkyl group having at least one hydroxyl group. In an embodiment, the hydroxyl group-containing (meth)acrylamide may include at least one of hydroxyethyl (meth)acrylamide, hydroxypropyl (meth)acrylamide, and hydroxybutyl (meth)acrylamide.

The hydroxyl group and alkylene glycol unit-containing (meth)acrylate may include a monofunctional (meth)acrylate having a hydroxyl group and a plurality of alkylene glycol units at an end thereof. The alkylene glycol units may be homogeneous or heterogeneous alkylene glycol units. The alkylene glycol units may include C₁ to C₅ alkylene glycol units, for example, ethylene glycol, and propylene glycol. In an embodiment, the hydroxyl group and alkylene glycol unit-containing (meth)acrylate may include at least one of terminal hydroxyl group-containing ethylene glycol mono(meth)acrylate and terminal hydroxyl group-containing propylene glycol mono(meth)acrylate.

The hydroxyl group-containing (meth)acrylic monomer may be present in an amount of about 4% by weight (wt %) to about 45 wt %, for example, about 4 wt % to about 40 wt %, about 4 wt % to about 35 wt %, about 4 wt % to about 10 wt %, or about 5 wt % to about 25 wt %, for example, about 4 wt %, about 5 wt %, about 6 wt %, about 7 wt %, about 8 wt %, about 9 wt %, about 10 wt %, about 11 wt %, about 12 wt %, about 13 wt %, about 14 wt %, about 15 wt %, about 16 wt %, about 17 wt %, about 18 wt %, about 19 wt %, about 20 wt %, about 21 wt %, about 22 wt %, about 23 wt %, about 24 wt %, about 25 wt %, about 26 wt %, about 27 wt %, about 28 wt %, about 29 wt %, about 30 wt %, about 31 wt %, about 32 wt %, about 33 wt %, about 34 wt %, about 35 wt %, about 36 wt %, about 37 wt %, about 38 wt %, about 39 wt %, about 40 wt %, about 41 wt %, about 42 wt %, about 43 wt %, about 44 wt %, or about 45 wt %, in the monomer mixture. Within this range, the adhesive film can exhibit further improved adhesion and durability.

The alkyl group-containing (meth)acrylic monomer forms a matrix of the adhesive film and may include an unsubstituted C₁ to C₂₀ alkyl group-containing (meth)acrylic acid ester. For example, the alkyl group-containing (meth)acrylic monomer may include at least one of methyl (meth)acrylate, ethyl (meth)acrylate, propyl (meth)acrylate, n-butyl (meth)acrylate, t-butyl (meth)acrylate, iso-butyl (meth)acrylate, pentyl (meth)acrylate, hexyl (meth)acrylate, heptyl (meth)acrylate, ethylhexyl (meth)acrylate, octyl (meth)acrylate, isooctyl (meth)acrylate, nonyl (meth)acrylate, decyl (meth)acrylate, and lauryl (meth)acrylate.

The alkyl group-containing (meth)acrylic monomer may be present in an amount of about 55 wt % to about 96 wt %, for example, about 60 wt % to about 95 wt %, about 70 wt % to about 96 wt %, about 85 wt % to about 95 wt %, or about 90 wt % to about 96 wt %, for example, about 55 wt %, about 56 wt %, about 57 wt %, about 58 wt %, about 59 wt %, about 60 wt %, about 61 wt %, about 62 wt %, about 63 wt %, about 64 wt %, about 65 wt %, about 66 wt %, about 67 wt %, about 68 wt %, about 69 wt %, about 70 wt %, about 71 wt %, about 72 wt %, about 73 wt %, about 74 wt %, about 75 wt %, about 76 wt %, about 77 wt %, about 78 wt %, about 79 wt %, about 80 wt %, about 81 wt %, about 82 wt %, about 83 wt %, about 84 wt %, about 85 wt %, about 86 wt %, about 87 wt %, about 88 wt %, about 89 wt %, about 90 wt %, about 91 wt %, about 92 wt %, about 93 wt %, about 94 wt %, about 95 wt %, or about 96 wt % in the monomer mixture. Within this range, the adhesive film can exhibit further improved adhesion and durability.

The copolymerizable monomer is different from the hydroxyl group-containing (meth)acrylic monomer and the alkyl group-containing (meth)acrylic monomer. The copolymerizable monomer may include at least one of an amine group-containing monomer, an amide group-containing monomer, an alkoxy group-containing monomer, a phosphate group-containing monomer, a sulfonate group-containing monomer, a phenyl group-containing monomer, an ethylene glycol unit-containing (meth)acrylate, a propylene glycol unit-containing (meth)acrylate, and an alicyclic group-containing monomer. The copolymerizable monomer may reduce the glass transition temperature of the (meth)acrylic copolymer, allow the adhesive film to maintain excellent adhesion even at low temperature (−20° C.) and to have similar modulus at high temperature (80° C.) and low temperature (−20° C.), further improve peel strength of the adhesive film at high temperature than at room temperature, or further improve peel strength of the adhesive film with respect to a non-surface-treated hydrophobic adherend.

The amine group-containing monomer may include any of amine group-containing (meth)acrylic monomers, such as monomethylaminoethyl (meth)acrylate, monoethylaminoethyl (meth)acrylate, monomethylaminopropyl (meth)acrylate, monoethylaminopropyl (meth)acrylate, dimethylaminoethyl (meth)acrylate, diethylaminoethyl (meth)acrylate, N-tert-butylaminoethyl (meth)acrylate, and methacryloxyethyltrimethyl ammonium chloride (meth)acrylate, without being limited thereto.

The amide group-containing monomer can improve the modulus of the adhesive film and suppress bubbling at high temperature. The amide group-containing monomer may include any of amide group-containing (meth)acrylic monomers, such as (meth)acrylamide, N-methyl acrylamide, N-methyl methacrylamide, N-methylol (meth)acrylamide, N-methoxymethyl (meth)acrylamide, and N,N-methylene bis(meth)acrylamide, without being limited thereto.

The alkoxy group-containing monomer may include any of 2-methoxyethyl (meth)acrylate, 2-methoxypropyl (meth)acrylate, 2-ethoxypropyl (meth)acrylate, 2-butoxypropyl (meth)acrylate, 2-methoxypentyl (meth)acrylate, 2-ethoxypentyl (meth)acrylate, 2-butoxyhexyl (meth)acrylate, 3-methoxypentyl (meth)acrylate, 3-ethoxypentyl (meth)acrylate, and 3-butoxyhexyl (meth)acrylate, without being limited thereto.

The phosphate group-containing monomer may include any of phosphate group-containing acrylic monomers, such as 2-methacryloyloxyethyldiphenylphosphate (meth)acrylate, trimethacryloyloxyethylphosphate (meth)acrylate, and triacryloyloxyethylphosphate (meth)acrylate, without being limited thereto.

The sulfonate group-containing monomer may include any of sulfonate group-containing acrylic monomers, such as sodium sulfopropyl (meth)acrylate, sodium 2-sulfoethyl (meth)acrylate, and sodium 2-acrylamido-2-methylpropane sulfonate, without being limited thereto.

The phenyl group-containing monomer may include any of phenyl group-containing acrylic vinyl monomers, such as p-tert-butylphenyl (meth)acrylate, o-biphenyl (meth)acrylate, and phenoxyethyl (meth)acrylate, without being limited thereto.

The ethylene glycol unit-containing (meth)acrylate may include at least one (meth)acrylate containing two or more ethylene glycol units. For example, the ethylene glycol unit-containing (meth)acrylate may include any of polyethylene glycol alkyl ether (meth)acrylates, such as polyethylene glycol monomethyl ether (meth)acrylate, polyethylene glycol monomethyl ether (meth)acrylate, polyethylene glycol monopropyl ether (meth)acrylate, polyethylene glycol monobutyl ether (meth)acrylate, polyethylene glycol monopentyl ether (meth)acrylate, polyethylene glycol dimethyl ether (meth)acrylate, polyethylene glycol diethyl ether (meth)acrylate, polyethylene glycol monoisopropyl ether (meth)acrylate, polyethylene glycol monoisobutyl ether (meth)acrylate, and polyethylene glycol mono-tert-butyl ether (meth)acrylate, without being limited thereto.

The propylene glycol unit-containing (meth)acrylate may include any of polypropylene glycol alkyl ether (meth)acrylates, such as polypropylene glycol monomethyl ether (meth)acrylate, polypropylene glycol monoethyl ether (meth)acrylate, polypropylene glycol monopropyl ether (meth)acrylate, polypropylene glycol monobutyl ether (meth)acrylate, polypropylene glycol monopentyl ether (meth)acrylate, polypropylene glycol dimethyl ether (meth)acrylate, polypropylene glycol diethyl ether (meth)acrylate, polypropylene glycol monoisopropyl ether (meth)acrylate, polypropylene glycol monoisobutyl ether (meth)acrylate, and polypropylene glycol mono-tert-butyl ether (meth)acrylate, without being limited thereto.

The alicyclic group-containing monomer can further improve peel strength of the adhesive film with respect to a non-surface-treated hydrophobic adherend. The alicyclic group-containing monomer is a C₃ to C₂₀ alicyclic group-containing (meth)acrylate, and may include at least one of isobornyl (meth)acrylate and dicyclopentadiene (meth)acrylate, without being limited thereto.

The copolymerizable monomer may be optionally present in an amount of about 10 wt % or less, and, in an embodiment, about 7 wt % or less to greater than 0 wt %, and, in one embodiment, about 0.1 wt % to about 10 wt %, and, in one embodiment, about 0.1 wt % to about 5 wt %, about 0.1 wt % to about 4 wt %, about 0.1 wt % to about 3 wt %, about 0.1 wt % to about 2 wt %, or about 0.1 wt % to about 1 wt %, for example, about 0.1 wt %, about 1 wt %, about 2 wt %, about 3 wt %, about 4 wt %, about 5 wt %, about 6 wt %, about 7 wt %, about 8 wt %, about 9 wt %, or about 10 wt % in the monomer mixture. Within this range, the adhesive film can exhibit better adhesion and durability. Preferably, the copolymerizable monomer includes the ethylene glycol unit-containing (meth)acrylate.

The monomer mixture may further include a carboxylic acid group-containing monomer. The carboxylic acid group-containing monomer may further improve peel strength of the adhesive sheet with respect to an adherend. The carboxylic acid group-containing monomer may include any of (meth)acrylic acid, 2-carboxyethyl (meth)acrylate, 3-carboxypropyl (meth)acrylate, 4-carboxybutyl (meth)acrylate, itaconic acid, crotonic acid, maleic acid, fumaric acid, and maleic anhydride, without being limited thereto. The carboxylic acid group-containing monomer may be optionally present in an amount of about 10 wt % or less, for example, about 0.1 wt % to about 10 wt %, about 0.1 wt % to about 5 wt %, about 1 wt % to about 5 wt %, about 2 wt % to about 5 wt %, or about 3 wt % to about 5 wt % in the monomer mixture. Within this range, the adhesive film can exhibit further improved adhesion and durability.

In one embodiment, the monomer mixture may include about 4 wt % to about 35 wt %, and, in an embodiment, about 5 wt % to about 25 wt % of the hydroxyl group-containing (meth)acrylic monomer, about 60 wt % to about 95 wt %, and, in an embodiment, about 85 wt % to about 95 wt % of the alkyl group-containing (meth)acrylic monomer, about 0.1 wt % to about 10 wt %, and, in an embodiment, about 0.1 wt % to about 5 wt % of the ethylene glycol unit-containing (meth)acrylate, and about 0.1 wt % to about 10 wt %, and, in an embodiment, about 0.1 wt % to about 5 wt % of the carboxylic acid group-containing monomer. Within this range, effects according to the present invention can be sufficiently realized.

The (meth)acrylic copolymer may have a weight average molecular weight of about 800,000 g/mol to about 3,000,000 g/mol, and, in an embodiment, about 1,500,000 g/mol to about 2,500,000 g/mol, for example, about 800,000, 900,000, 1,000,000, 1,100,000, 1,200,000, 1,300,000, 1,400,000, 1,500,000, 1,600,000, 1,700,000, 1,800,000, 1,900,000, 2,000,000, 2,100,000, 2,200,000, 2,300,000, 2,400,000, 2,500,000, 2,600,000, 2,700,000, 2,800,000, 2,900,000, or 3,000,000 g/mol. Within this range, the adhesive film can exhibit improved flexibility. Herein, the “weight average molecular weight” may be measured by gel permeation chromatography (GPC). Specifically, the weight average molecular weight may be measured by GPC at a mobile phase flow rate of 1.0 ml/minute at an analysis temperature of 40° C. using an Alliance 2690 (Waters Co., Ltd.) as a GPC system; two PLgel mixed C columns; tetrahydrofuran (THF) as a mobile phase; and a refractive index detector (RID).

The (meth)acrylic copolymer may be prepared by polymerizing the monomer mixture in a typical manner. For example, the (meth)acrylic copolymer may be prepared by adding the initiator, for example, azobisisobutyronitrile, to the monomer mixture, followed by performing solution polymerization, suspension polymerization, emulsion polymerization, or the like. Polymerization may be performed at 50° C. to 200° C. for 30 minutes to 10 hours, without being limited thereto.

The monofunctional (meth)acrylic monomer is cured in conjunction with the polyfunctional (meth)acrylic monomer, thereby providing flexural properties, good foldability, and high peel strength at high-temperature to the adhesive film while facilitating formation of regions having different moduli depending upon a degree of curing of a coating layer.

The monofunctional (meth)acrylic monomer may have a molecular weight of about 80 g/mol to about 1,000 g/mol. Within this range, the monofunctional (meth)acrylic monomer can improve transparency of the adhesive film by suppressing phase separation when mixed with the (meth)acrylic copolymer and the polyfunctional (meth)acrylic monomer. The monofunctional (meth)acrylic monomer may be a non-urethane monomer not having a urethane group. Therefore, the adhesive film has reduced glass transition temperature and modulus, thereby exhibiting excellent foldability at low temperature and at high temperature and humidity. The monofunctional (meth)acrylic monomer may have a boiling point of about 200° C. or more, and, in an embodiment, about 200° C. to about 400° C. Within this range, the monofunctional (meth)acrylic monomer is not volatilized even though a solvent in the adhesive composition is dried.

The monofunctional (meth)acrylic monomer may include any of isobornyl (meth)acrylate, 2-ethylhexyl (meth)acrylate, isooctyl (meth)acrylate, lauryl (meth)acrylate, hydroxypropyl (meth)acrylate, hydroxyethyl (meth)acrylate, stearyl (meth)acrylate, 3-trimethoxysilylpropyl (meth)acrylate, diacetone (meth)acrylamide, (meth)acrylamide, 2-(2-ethoxyethoxy)ethyl (meth)acrylate, 2-methoxyethyl (meth)acrylate, tetrahydrofurfuryl (meth)acrylate, ethylene glycol phenyl ether (meth)acrylate, isodecyl (meth)acrylate, 2-(meth)acryloyloxyethyl succinate, isononyl (meth)acrylate, isostearyl (meth)acrylate, caprolactone (meth)acrylate, N,N-dimethyl (meth)acrylamide, octyl (meth)acrylate, octadecyl (meth)acrylate, tert-butyl (meth)acrylate, hydroxybutyl (meth)acrylate, dicyclopentadiene (meth)acrylate, acryloylmorpholine, cyclohexyl methacrylate, an aromatic (meth)acrylate, and the like. The aromatic (meth)acrylate may be represented by Formula 1:

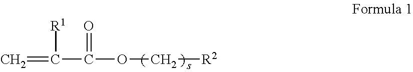

where R¹ is hydrogen or a methyl group, s is an integer of 0 to 10, and R² is a substituted or unsubstituted C₆ to C₅₀ aryl group or a substituted or unsubstituted C₆ to C₅₀ aryloxy group. The term “substituted” in the term “substituted or unsubstituted” means that at least one hydrogen atom is substituted with a C₁ to C₁₀ alkyl group, a C₁ to C₁₀ thioalkyl group, a C₁ to C₁₀ alkoxy group, a halogen (F, Cl, Br or I), a C₃ to C₁₀ cycloalkyl group, or a C₆ to C₂₀ aryl group.

In an embodiment, R² may include substituted or unsubstituted phenoxy, benzyl, phenyl, biphenyl, terphenyl, phenylphenyl groups, and the like. In an embodiment, the aromatic (meth)acrylate may include at least one of phenoxy methacrylate, 2-ethylphenoxy methacrylate, benzyl methacrylate, phenyl methacrylate, 2-ethylthiophenyl methacrylate, 2-phenylethyl methacrylate, 3-phenylpropyl methacrylate, 4-phenylbutyl methacrylate, 2-(2-methylphenyl)ethyl methacrylate, 2-(3-methylphenyl)ethyl methacrylate, 2-(4-methylphenyl)ethyl methacrylate, 2-(4-propylphenyl)ethyl methacrylate, 2-(4-(1-methylethyl)phenyl)ethyl methacrylate, 2-(4-methoxyphenyl)ethyl methacrylate, 2-(4-cyclohexylphenyl)ethyl methacrylate, 2-(2-chlorophenyl)ethyl methacrylate, 2-(3-chlorophenyl)ethyl methacrylate, 2-(4-chlorophenyl)ethyl methacrylate, 2-(4-bromophenyl)ethyl methacrylate, 2-(3-phenylphenyl)ethyl methacrylate, ortho-biphenyl methacrylate, meta-biphenyl methacrylate, para-biphenyl methacrylate, 2,6-terphenyl methacrylate, ortho-terphenyl methacrylate, meta-terphenyl methacrylate, para-terphenyl methacrylate, 4-(4-methylphenyl)phenyl methacrylate, 4-(2-methylphenyl)phenyl methacrylate, 2-(4-methylphenyl)phenyl methacrylate, 2-(2-methylphenyl)phenyl methacrylate, 4-(4-ethylphenyl)phenyl methacrylate, 4-(2-ethylphenyl)phenyl methacrylate, 2-(4-ethylphenyl)phenyl methacrylate, and 2-(2-ethylphenyl)phenyl methacrylate. These aromatic (meth)acrylates may be used alone or in combination thereof.

The monofunctional (meth)acrylic monomer may be a mixture of a first monofunctional (meth)acrylic monomer; and at least one of a second monofunctional (meth)acrylic monomer and a third monofunctional (meth)acrylic monomer. The first, second, and third monofunctional (meth)acrylic monomers are different from each other.

In one embodiment, a weight ratio of the first monofunctional (meth)acrylic monomer to the second monofunctional (meth)acrylic monomer (first monofunctional (meth)acrylic monomer:second monofunctional (meth)acrylic monomer) in the mixture may be in a range from about 4:1 to about 0.2:1. In another embodiment, the first, second, and third monofunctional (meth)acrylic monomers may be present in a weight ratio of about 0.5 to about 5:about 0.5 to about 1:about 1 (first monofunctional (meth)acrylic monomer:second monofunctional (meth)acrylic monomer:third monofunctional (meth)acrylic monomer). Within this range, the adhesive film can have excellent flexural properties.

The first monofunctional (meth)acrylic monomer may include at least one of isobornyl (meth)acrylate, the aromatic acrylates set forth above, acryloylmorpholine, and dicyclopentadiene (meth)acrylate. The second monofunctional (meth)acrylic monomer may include at least one of hydroxypropyl (meth)acrylate, hydroxybutyl acrylate, and hydroxyethyl methacrylate. The third monofunctional (meth)acrylic monomer may include at least one of 2-(2-ethoxyethoxy)ethyl (meth)acrylate, N,N-dimethyl (meth)acrylamide, 2-ethylhexyl acrylate, isooctyl acrylate, octadecyl acrylate, lauryl acrylate, and tert-butyl acrylate.

The monofunctional (meth)acrylic monomer and the polyfunctional (meth)acrylic monomer may be present in a weight ratio of about 1:1 to about 5:1, and, in an embodiment, about 1.1:1 to about 5:1, for example, about 1:1, about 1.2:1, about 2:1, about 3:1, about 4:1, or about 5:1 (monofunctional (meth)acrylic monomer:polyfunctional (meth)acrylic monomer). Within this range, the adhesive film can be easily handled and exhibit excellent foldability.

The monofunctional (meth)acrylic monomer may be present in an amount of about 1 part by weight to about 60 parts by weight, and, in an embodiment, about 20 parts by weight to about 50 parts by weight, for example, about 1, 2, 3, 4, 5, 6, 7, 8, 9, 10, 11, 12, 13, 14, 15, 16, 17, 18, 19, 20, 21, 22, 23, 24, 25, 26 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, or 60 parts by weight relative to 100 parts by weight of the (meth)acrylic copolymer. Within this range, the adhesive film can have reduced glass transition temperature and/or improved adhesion.

The polyfunctional (meth)acrylic monomer can provide flexural properties, good foldability, and a plurality of regions having different moduli depending upon the degree of curing of the adhesive film together with the monofunctional (meth)acrylic monomer, as described above. The polyfunctional (meth)acrylic monomer can improve modulus of an adhesive layer by improving a degree of crosslinking of the adhesive layer.

The polyfunctional (meth)acrylic monomer may be a non-urethane monomer not having a urethane group. Thus, the polyfunctional (meth)acrylic monomer can be effective in improving the modulus of a non-bending region of the adhesive film by allowing the adhesive film to have a densely crosslinked structure. The polyfunctional (meth)acrylic monomer may have a boiling point of about 200° C. or more, and, in an embodiment, about 200° C. to about 400° C. Within this range, the polyfunctional (meth)acrylic monomer is not volatilized even though the adhesive film is formed by drying a solvent in the adhesive composition. The polyfunctional (meth)acrylic monomer may have a molecular weight of about 800 g/mol to about 2,000 g/mol. Within this range, the polyfunctional (meth)acrylic monomer can suppress phase separation while improving transparency of the adhesive film.

The polyfunctional (meth)acrylic monomer may include a (meth)acrylic monomer having two or more, and, in an embodiment, two to six (meth)acrylate groups. For example, the polyfunctional (meth)acrylic monomer may include: bifunctional (meth)acrylates, such as 1,4-butanediol di(meth)acrylate, 1,6-hexanediol di(meth)acrylate, neopentylglycol di(meth)acrylate, polyethylene glycol di(meth)acrylate, neopentylglycol adipate di(meth)acrylate, dicyclopentanyl di(meth)acrylate, caprolactone-modified dicyclopentenyl di(meth)acrylate, ethylene oxide-modified di(meth)acrylate, di(meth)acryloxyethyl isocyanurate, allylated cyclohexyl di(meth)acrylate, tricyclodecane dimethanol di(meth)acrylate, dimethylol dicyclopentane di(meth)acrylate, ethylene oxide-modified hexahydrophthalic acid di(meth)acrylate, neopentylglycol-modified trimethylpropane di(meth)acrylate, adamantane di(meth)acrylate, 9,9-bis[4-(2-acryloyloxyethoxy)phenyl] fluorene, and the like; trifunctional (meth)acrylates, such as trimethylolpropane tri(meth)acrylate, dipentaerythritol tri(meth)acrylate, propionic acid-modified dipentaerythritol tri(meth)acrylate, pentaerythritol tri(meth)acrylate, propylene oxide-modified trimethylolpropane tri(meth)acrylate, tris(meth)acryloxyethyl isocyanurate, and the like; tetrafunctional (meth)acrylates, such as diglycerin tetra(meth)acrylate, pentaerythritol tetra(meth)acrylate, and the like; pentafunctional (meth)acrylates, such as dipentaerythritol penta(meth)acrylate and the like; hexafunctional (meth)acrylates, such as dipentaerythritol hexa(meth)acrylate, caprolactone-modified dipentaerythritol hexa(meth)acrylate, and the like, without being limited thereto. These polyfunctional (meth)acrylic monomers may be used alone or in combination thereof. In an embodiment, the polyfunctional (meth)acrylic monomer may include tetrafunctional (meth)acrylates, such as pentaerythritol tetra(meth)acrylate. In this case, the adhesive film can exhibit good flexural properties and foldability after curing.

The polyfunctional (meth)acrylic monomer may be present in an amount of about 1 part by weight to about 50 parts by weight, and, in an embodiment, about 15 parts by weight to about 30 parts by weight, or about 15 parts by weight to about 25 parts, for example, about 1, 2, 3, 4, 5, 6, 7, 8, 9, 10, 11, 12, 13, 14, 15, 16, 17, 18, 19, 20, 21, 22, 23, 24, 25, 26 27, 28, 29, 30, 31, 32, 33, 34, 35, 36, 37, 38, 39, 40, 41, 42, 43, 44, 45, 46, 47, 48, 49, or 50 parts by weight relative to 100 parts by weight of the (meth)acrylic copolymer. Within this range, the adhesive film can have improved modulus due to a densely crosslinked structure thereof.

The initiator may cure the (meth)acrylic copolymer, the monofunctional (meth)acrylic monomer, and the polyfunctional (meth)acrylic monomer. The initiator may include a photo initiator. For example, the photo initiator may include any of benzoin, hydroxy ketone, amino ketone, phosphine oxide photoinitiators, and the like. In an embodiment, the photo initiator may include any of hydroxy ketone photoinitiators, such as 1-hydroxycyclohexyl phenyl ketone and the like, benzoin, benzoin methyl ether, benzoin ethyl ether, benzoin isopropyl ether, benzoin n-butyl ether, benzoin isobutyl ether, acetophenone compounds, such as 2,2-dimethoxy-2-phenylacetophenone, 2,2′-diethoxyacetophenone, 2,2′-dibutoxyacetophenone, 2-hydroxy-2-methylpropiophenone, p-t-butyltrichloroacetophenone, p-t-butyldichloroacetophenone, 4-chloroacetophenone, 2,2′-dichloro-4-phenoxyacetophenone, and the like, dimethylaminoacetophenone, 2,2-dimethoxy-2-phenylacetophenone, 2,2-diethoxy-2-phenylacetophenone, 2-hydroxy-2-methyl-1-phenylpropan-1-one, 2-benzyl-2-dimethyl amino-1-(4-morpholinophenyl)-butan-1-one, 1-hydroxycyclohexyl phenyl ketone, 2-methyl-1-[4-(methylthio)phenyl]-2-morpholino-propan-1-one, 4-(2-hydroxyethoxy)phenyl-2-(hydroxy-2-propyl)ketone, benzophenone, p-phenylbenzophenone, 4,4-diethylaminobenzophenone, dichlorobenzophenone, 2-methylanthraquinone, 2-ethylanthraquinone, 2-t-butylanthraquinone, 2-am inoanthraquinone, 2-methyl thioxanthone, 2-ethylthioxanthone, 2-chlorothioxanthone, 2,4-dimethylthioxanthone, 2,4-diethylthioxanthone, benzyl dimethyl ketal, acetophenone dimethyl ketal, p-dimethylaminobenzoic acid ester, oligo[2-hydroxy-2-methyl-1-[4-(1-methylvinyl)phenyl] propanone], and 2,4,6-trimethylbenzoyl-diphenyl-phosphine oxide. Preferably, the photo initiator includes any of hydroxy ketone photoinitiators, acetophenone compounds, benzyl ketal type compounds, and mixtures thereof, without being limited thereto.

The initiator may be present in an amount of about 0.001 parts by weight to about 5 parts by weight, and, in an embodiment, about 0.05 parts by weight to about 3 parts by weight relative to 100 parts by weight of the total amount of the monofunctional (meth)acrylic monomer and the polyfunctional (meth)acrylic monomer. Within this range, curing can be completely performed, deterioration in transmittance of the adhesive film due to the residual initiator can be prevented or substantially prevented, bubble generation in the adhesive composition can be reduced, and the adhesive film can have excellent reactivity.

The adhesive composition may further include a silane coupling agent. The silane coupling agent can further improve adhesion of the adhesive film to an adherend (for example, a glass plate). The silane coupling agent may be a typical silane coupling agent known to those skilled in the art. For example, the silane coupling agent may include at least one selected from the group consisting of epoxylated silicon compounds, such as 3-glycidoxypropyltrimethoxysilane, 3-glycidoxypropyltriethoxysilane, 3-glycidoxypropylmethyldimethoxysilane, and 2-(3,4-epoxycyclohexyl)ethyltrimethoxysilane; polymerizable unsaturated group-containing silicon compounds, such as vinyltrimethoxysilane, vinyltriethoxysilane, and (meth)acryloxypropyltrimethoxysilane; amino group-containing silicon compounds, such as 3-am inopropyltrimethoxysilane, N-(2-am inoethyl)-3-am inopropyltrimethoxysilane, and N-(2-am inoethyl)-3-am inopropylmethyldimethoxysilane; and 3-chloropropyltrimethoxysilane, without being limited thereto. Preferably, the silane coupling agent includes any of epoxylated silane coupling agents, without being limited thereto.

The silane coupling agent may be present in an amount of about 0.01 parts by weight to about 0.1 parts by weight, and, in an embodiment, about 0.05 parts by weight to about 0.1 parts by weight relative to 100 parts by weight of the (meth)acrylic copolymer. Within this range, the adhesive film exhibit improved reliability.

The adhesive composition may further include typical additives, such as curing accelerators, ionic liquids, lithium salts, inorganic fillers, softeners, molecular weight regulators, antioxidants, anti-aging agents, stabilizers, adhesion-imparting resins, reforming resins (polyol, phenol, acrylic, polyester, polyolefin, epoxy, epoxidized polybutadiene resins, and the like), leveling agents, defoamers, plasticizers, dyes, pigments (coloring pigments, extender pigments, and the like), processing agents, UV blocking agents, fluorescent whitening agents, dispersants, heat stabilizers, photostabilizers, UV absorbers, antistatic agents, coagulants, lubricants, solvents, and the like.

According to another embodiment of the invention, an adhesive composition may include: a monomer mixture including a hydroxyl group-containing (meth)acrylate and a comonomer; and organic nanoparticles.

A hydroxyl group-containing (meth)acrylic copolymer, which is polymerized from the monomer mixture including the hydroxyl group-containing (meth)acrylate and the comonomer, forms a matrix of an adhesive film and can provide adhesion to the adhesive film. The hydroxyl group-containing (meth)acrylic copolymer may have a glass transition temperature of about −150° C. to about −13° C., and, in an embodiment, about −100° C. to about −20° C., for example, about −150, −140, −130, −120, −110, −100, −90, −80, −70, −60, −50, −40, −30, −20, or −13° C. Within this range, the adhesive film exhibits excellent foldability and has excellent adhesion and reliability in a wide temperature range. The term “comonomer” as used herein may refer to a monomer that is different from a hydroxyl group-containing (meth)acrylic monomer.

Details of the hydroxyl group-containing (meth)acrylic monomer have been described in relation to the adhesive composition according to the above embodiment.

The hydroxyl group-containing (meth)acrylic monomer may be present in an amount of about 5 wt % to about 40 wt %, for example, about 10 wt % to about 30 wt %, for example, about 5 wt %, about 6 wt %, about 7 wt %, about 8 wt %, about 9 wt %, about 10 wt %, about 11 wt %, about 12 wt %, about 13 wt %, about 14 wt %, about 15 wt %, about 16 wt %, about 17 wt %, about 18 wt %, about 19 wt %, about 20 wt %, about 21 wt %, about 22 wt %, about 23 wt %, about 24 wt %, about 25 wt %, about 26 wt %, about 27 wt %, about 28 wt %, about 29 wt %, about 30 wt %, about 31 wt %, about 32 wt %, about 33 wt %, about 34 wt %, about 35 wt %, about 36 wt %, about 37 wt %, about 38 wt %, about 39 wt %, or about 40 wt % in the monomer mixture. Within this range, the adhesive film can have low haze and excellent adhesion.

The comonomer may include at least one of an alkyl group-containing (meth)acrylic monomer, an ethylene glycol unit-containing (meth)acrylate, a propylene glycol unit-containing (meth)acrylate, an amine group-containing monomer, an amide group-containing monomer, an alkoxy group-containing monomer, a phosphate group-containing monomer, a sulfonate group-containing monomer, a phenyl group-containing monomer, a silane group-containing monomer, and an alicyclic group-containing monomer, without being limited thereto. Details of the comonomer have been described in relation to the adhesive composition according to the above-described embodiment of the present invention. The comonomer may be present in an amount of about 60 wt % to about 95 wt %, and, in an embodiment, about 70 wt % to about 90 wt %, for example, about 60 wt %, about 61 wt %, about 62 wt %, about 63 wt %, about 64 wt %, about 65 wt %, about 66 wt %, about 67 wt %, about 68 wt %, about 69 wt %, about 70 wt %, about 71 wt %, about 72 wt %, about 73 wt %, about 74 wt %, about 75 wt %, about 76 wt %, about 77 wt %, about 78 wt %, about 79 wt %, about 80 wt %, about 81 wt %, about 82 wt %, about 83 wt %, about 84 wt %, about 85 wt %, about 86 wt %, about 87 wt %, about 88 wt %, about 89 wt %, about 90 wt %, about 91 wt %, about 92 wt %, about 93 wt %, about 94 wt %, or about 95 wt % in the monomer mixture. Within this range, the adhesive film has excellent adhesion and reliability.

In one embodiment, the hydroxyl group-containing (meth)acrylic copolymer may be a copolymer of the monomer mixture including the hydroxyl group-containing (meth)acrylic monomer and the comonomer having a glass transition temperature of about −150° C. to about 0° C. as measured on a homopolymer of the comonomer. The “glass transition temperature” may be measured on a homopolymer of each measurement target monomer using a DSC Q20 (TA Instrument Inc.). Specifically, a homopolymer of each monomer is heated to 180° C. at a rate of 20° C./min, slowly cooled to −180° C., and heated to 100° C. at a rate of 10° C./min, thereby obtaining data of an endothermic transition curve. An inflection point of the endothermic transition curve is determined as the glass transition temperature.

In an embodiment, the comonomer may have a glass transition temperature of about −150° C. to about −20° C., and, in one embodiment, about −150° C. to about −40° C. Within this range, the adhesive film can exhibit excellent foldability at low temperature. For example, the comonomer may include at least one of alkyl (meth)acrylate monomers including methyl acrylate, ethyl acrylate, isopropyl acrylate, n-butyl acrylate, iso-butyl acrylate, hexyl (meth)acrylate, heptyl (meth)acrylate, 2-ethylhexyl acrylate, dodecyl (meth)acrylate, and the like; alkylene oxide group-containing (meth)acrylate monomers including polyethylene oxide monomethyl ether (meth)acrylate, polyethylene oxide monoethyl ether (meth)acrylate, polyethylene oxide monopropyl ether (meth)acrylate, polyethylene oxide monobutyl ether (meth)acrylate, polyethylene oxide monopentyl ether (meth)acrylate, polypropylene oxide monomethyl ether (meth)acrylate, polypropylene oxide monoethyl ether (meth)acrylate, polypropylene oxide monopropyl ether (meth)acrylate, and the like; amino group-containing (meth)acrylate monomers including monomethylaminoethyl (meth)acrylate, monoethylaminoethyl (meth)acrylate, monomethylaminopropyl (meth)acrylate, monoethylaminopropyl (meth)acrylate, and the like; alkoxy group-containing (meth)acrylate monomers including 2-methoxyethyl (meth)acrylate, 2-methoxypropyl (meth)acrylate, 2-ethoxypropyl (meth)acrylate and the like; and silane group-containing (meth)acrylate monomers including 2-acetoacetoxyethyl (meth)acrylate, vinyltrimethoxysilane, vinyltriethoxysilane, and the like.

The monomer mixture may further include a carboxylic acid group-containing monomer. The carboxylic acid-containing monomer may be present in an amount of about 10 wt % or less, and, in an embodiment, about 7 wt % or less, or about 5 wt % or less in the monomer mixture. Within this range, the adhesive film exhibits good adhesion and excellent reliability. Details of the carboxylic acid-containing monomer have been described in relation to the adhesive composition according to the above embodiment.

The organic nanoparticles are included in the adhesive composition or the adhesive film, whereby the adhesive film has excellent viscoelasticity and exhibits stable high temperature viscoelasticity due to a crosslinked structure thereof. In one embodiment, the organic nanoparticles may form a chemical bond to the hydroxyl group-containing (meth)acrylic copolymer. In an embodiment, although the adhesive composition or the adhesive film includes the organic nanoparticles, there is a specific difference in index of refraction between the organic nanoparticles having a specific average particle size and the hydroxyl group-containing (meth)acrylic copolymer, as described below, whereby the adhesive film can have excellent transparency.

The organic nanoparticles may have an average particle diameter of about 10 nm to about 400 nm, and, in an embodiment, about 10 nm to about 300 nm, and, in one embodiment, about 10 nm to about 200 nm, for example, about 10, 20, 30, 40, 50, 60, 70, 80, 90, 100, 110, 120, 130, 140, 150, 160, 170, 180, 190, 200, 210, 220, 230, 240, 250, 260, 270, 280, 290, 300, 310, 320, 330, 340, 350, 360, 370, 380, 390, or 400 nm. Within this range, agglomeration of the organic nanoparticles can be prevented or substantially prevented, and the adhesive film has excellent transparency.

A difference in index of refraction between the organic nanoparticles and the hydroxyl group-containing (meth)acrylic copolymer may be about 0.1 or less, and, in an embodiment, from about 0 to about 0.05, and, in one embodiment, from about 0 to about 0.03, for example, about 0, 0.01, 0.02, 0.03, 0.04, 0.05, 0.06, 0.07, 0.08, 0.09, or 0.1. Within this range, the adhesive film has excellent transparency.

The organic nanoparticles have a core-shell structure, in which the core and the shell may have a glass transition temperature satisfying the following Equation 1:

Tg(c)<Tg(s) Equation 1

where Tg (c) is a glass transition temperature (° C.) of the core, and Tg (s) is a glass transition temperature (° C.) of the shell.

The core may have a glass transition temperature of about −150° C. to about 10° C., and, in an embodiment, about −150° C. to about −5° C., and, in one embodiment, about −150° C. to about −20° C., for example, about −150, −140, −130, −120, −110, −100, −90, −80, −70, −60, −50, −40, −30, −20, −10, 0, or 10° C. Within this range, the adhesive film can realize storage modulus required at low temperatures (−20° C.) and exhibits excellent low temperature and/or room temperature viscoelasticity. In an embodiment, the core may include at least one of poly(alkyl (meth)acrylates) having a glass transition temperature as set forth above. For example, the core may include at least one of poly(methyl acrylate), poly(ethyl acrylate), poly(propyl acrylate), poly(butyl acrylate), poly(isopropyl acrylate), poly(hexyl acrylate), poly(hexyl methacrylate), poly(ethylhexyl acrylate), and poly(ethylhexyl methacrylate), without being limited thereto. In one embodiment, the core may include at least one of poly(butyl acrylate) and poly(ethylhexyl acrylate).

The shell may have a glass transition temperature of about 15° C. to about 150° C., and, in an embodiment, about 35° C. to about 150° C., and, in one embodiment, about 50° C. to about 140° C., for example, about 15, 20, 30, 40, 50, 60, 70, 80, 90, 100, 110, 120, 130, 140, or 150° C. Within this range, the organic nanoparticles have excellent dispersibility in the hydroxyl group-containing (meth)acrylic copolymer. In an embodiment, the shell may include any of polyalkyl (meth)acrylates having a glass transition temperature as set forth above. For example, the shell may include at least one of poly(methyl methacrylate) (PMMA), poly(ethyl methacrylate), poly(propyl methacrylate), poly(butyl methacrylate), poly(isopropyl methacrylate), poly(isobutyl methacrylate), and poly(cyclohexyl methacrylate), without being limited thereto. In one embodiment, the shell may include poly(methyl methacrylate).

In another embodiment, the core or the shell may include two or more layers, and an outermost layer of the organic nanoparticles may include at least one of polyalkyl (meth)acrylates having a glass transition temperature of about 15° C. to about 150° C. In an embodiment, the core may include at least one of polyalkyl (meth)acrylates having a glass transition temperature of about −150° C. to about 10° C., and may also include at least one of polyalkyl (meth)acrylates without limitation of glass transition temperature while allowing the glass transition temperature of the overall core to be about −150° C. to about 10° C., without being limited thereto. In addition, the shell may include at least one of polyalkyl (meth)acrylates having a glass transition temperature of about 15° C. to about 150° C., and may also include at least one of polyalkyl (meth)acrylates without limitation of glass transition temperature while allowing the glass transition temperature of the overall shell to be about 15° C. to about 150° C., without being limited thereto.

The shell may be present in an amount of about 1 wt % to about 70 wt %, and, in an embodiment, about 5 wt % to about 60 wt %, and, in one embodiment, about 10 wt % to about 50 wt %, for example, about 1, 5, 10, 15, 20, 25, 30, 35, 40, 45, 50, 55, 60, 65, or 70 wt % in the organic nanoparticles. The core may be present in an amount of about 30 wt % to about 99 wt %, and, in an embodiment, about 40 wt % to about 95 wt %, and, in one embodiment, about 50 wt % to about 90 wt %, for example, about 30, 35, 40, 45, 50, 55, 60, 65, 70, 75, 80, 85, 90, 95, or 99 wt % in the organic nanoparticles. Within these ranges of the amounts of the shell and the core, the adhesive film can maintain viscoelasticity in a wide temperature range and have excellent recovery rate.

The organic nanoparticles may be present in an amount of about 0.1 parts by weight to about 15 parts by weight, and, in an embodiment, about 0.5 parts by weight to about 10 parts by weight, and, in one embodiment, about 0.5 parts by weight to about 8 parts by weight, for example, about 0.1, 1, 2, 3, 4, 5, 6, 7, 8, 9, 10, 11, 12, 13, 14, or 15 parts by weight relative to 100 parts by weight of the monomer mixture including the hydroxyl group-containing (meth)acrylate and the comonomer. Within this range, the adhesive film can have balance between viscoelasticity, storage modulus, and recovery rate.

In one embodiment, a syrup including the hydroxyl group-containing (meth)acrylic copolymer (prepolymer) may be prepared by adding an initiator to the monomer mixture and performing partial polymerization of the monomer mixture, followed by introducing the organic nanoparticles into the syrup, thereby preparing the adhesive composition. Alternatively, an initiator may be added to a mixture including the hydroxyl group-containing (meth)acrylic monomer, the comonomer (for example, the comonomer having a glass transition temperature (Tg) of −150° C. to 0° C. as measured on a homopolymer thereof) and the organic nanoparticles, followed by performing partial polymerization of the mixture, thereby preparing a syrup including the hydroxyl group-containing (meth)acrylic copolymer (prepolymer).

The adhesive composition may further include at least one of the initiator, the polyfunctional (meth)acrylic monomer, the silane coupling agent, and the additives, which are described above.

The initiator may be present in an amount of about 0.01 parts by weight to about 5 parts by weight, and, in an embodiment, about 0.05 parts by weight to about 3 parts by weight, and, in one embodiment, about 0.1 parts by weight to about 1 part by weight relative to 100 parts by weight of the monomer mixture including the hydroxyl group-containing (meth)acrylate and the comonomer. Within this range, curing of the adhesive composition can be completely performed, and deterioration in transmittance of the adhesive film due to the residual initiator can be prevented or substantially prevented.

The polyfunctional (meth)acrylic monomer may be present in an amount of about 0.01 parts by weight to about 10 parts by weight, and, in an embodiment, about 0.03 parts by weight to about 7 parts by weight, and, in one embodiment, about 0.1 parts by weight to about 5 parts by weight, for example, about 0.01, 1, 2, 3, 4, 5, 6, 7, 8, 9, or 10 parts by weight relative to 100 parts by weight of the monomer mixture including the hydroxyl group-containing (meth)acrylate and the comonomer. Within this range, the adhesive film has excellent adhesion and improved reliability.

The silane coupling agent may be present in an amount of about 0.01 parts by weight to about 0.1 parts by weight, and, in an embodiment, about 0.05 parts by weight to about 0.1 parts by weight relative to 100 parts by weight of the monomer mixture including the hydroxyl group-containing (meth)acrylate and the comonomer. Within this range, the adhesive film exhibits improved reliability.

A method of manufacturing the adhesive sheet according to an embodiment of the present invention will be described.

The adhesive composition may be coated to a certain thickness onto a release film and dried, thereby forming an adhesive layer. Next, the overall adhesive layer may be subjected to first UV irradiation at a UV dose of about 200 mJ/cm² to about 3,000 mJ/cm² (UV irradiance: about 400 mW/cm² to about 1,000 mW/cm²), and, in an embodiment, about 200 mJ/cm² to about 400 mJ/cm², followed by masking a portion of the adhesive layer, which corresponds to the region M1, with a mask, and then subjected to second UV irradiation at a UV dose of about 500 mJ/cm² to about 3,000 mJ/cm² (UV irradiance: about 400 mW/cm² to about 1,000 mW/cm²), thereby manufacturing an adhesive sheet according to an embodiment of the present invention, such as the adhesive sheet 10 according to the above-described embodiment.

An adhesive sheet according to another embodiment of the present invention will be described with reference to FIG. 2. FIG. 2 is a perspective view of an adhesive sheet according to another embodiment of the present invention.

Referring to FIG. 2, an adhesive sheet 20 according to another embodiment may include an adhesive film SA2 including a first region M1, second regions M2, and third regions M3; the second regions M2 and the third regions M3 may be coplanar with the first region M1; the second regions M2 may have higher modulus than the third regions M3; and the third regions M3 may have higher modulus than the first region M1. The first region M1 is formed between a third region M3 and an adjacent third region M3, and the first region M1, the second regions M2, and the third regions M3 are formed as one body. The adhesive sheet 20 is substantially the same as the adhesive sheet 10 described above except that the third regions M3 are further formed between the first region M1 and the second regions M2. The third regions M3 have modulus between modulus of the first region M1 and modulus of the second regions M2, thereby buffering a difference in modulus between the first region M1 and the second regions M2.

An adhesive sheet according to another embodiment of the present invention will be described.

The adhesive sheet according to another embodiment may include an adhesive film including a first region and two or more regions coplanar with the first region and having a higher modulus than the first region, and may further include an impact dispersion film on a surface of the adhesive sheet. When a display device, for example, an organic light emitting device or an organic light emitting device-containing panel is bonded to the adhesive sheet, the impact dispersion film can protect the display device from external impact and thus further improve impact resistance of the adhesive sheet.

An adhesive sheet according to another embodiment of the present invention will be described with reference to FIG. 3. FIG. 3 is a perspective view of an adhesive sheet according to another embodiment of the present invention.

Referring to FIG. 3, an adhesive sheet 30 according to another embodiment may include an adhesive film SA1 including a first region M1 and second regions M2, and an impact dispersion film SD formed on a lower surface of the adhesive film SA1. The second regions M2 may be coplanar with the first region M1 and have higher modulus than the first region M1. The adhesive sheet 30 is substantially the same as the adhesive sheet 10 described above except that the impact dispersion film SD is further formed on lower surfaces of the first region M1 and the second regions M2. Therefore, the following description will focus on the impact dispersion film SD.

The impact dispersion film SD may be formed on the lower surfaces of the first region M1 and the second regions M2 to support the first region M1 and the second regions M2. In addition, when a display device, for example, an organic light emitting device or an organic light emitting device-containing panel, is bonded to the adhesive sheet 30, the impact dispersion film SD can protect the display device by dispersing external impact applied to the display device.

The impact dispersion film SD may have a higher modulus than the first region M1 and the second regions M2. In an embodiment, the impact dispersion film SD may have a modulus at 25° C. of about 100 MPa or more, and, in an embodiment, about 100 MPa to about 7,000 MPa, for example, about 100, 500, 1,000, 1,500, 2,000, 2,500, 3,000, 3,500, 4,000, 4,500, 5,000, 5,500, 6,000, 6,500, or 7,000 MPa. Within this range, the impact dispersion film SD can have a great effect of protecting the display device from external impact. The impact dispersion film SD may have a thickness of less than about 150 μm, and, in an embodiment, about 20 μm to about 100 μm, for example, about 20, 30, 40, 50, 60, 70, 80, 90, 100, 110, 120, 130, 140, or 150 μm. Within this range, the impact dispersion film SD can protect the display device from external impact. The impact dispersion film SD may be formed of a non-adhesive and optically transparent resin. For example, the transparent resin may include at least one of polyester resins such as polyethylene terephthalate and polyethylene naphthalate, polyimide resins, polyamide resins, and polyethersulfone resins. In FIG. 3, the adhesive film SA1 is shown as directly contacting the impact dispersion film SD. However, in an embodiment, a functional layer having a function of protecting the display device from external impact may be formed between the impact dispersion film SD and the adhesive film SA1.

A flexible display according to embodiments of the present invention may include the adhesive film according to an embodiment of the present invention.

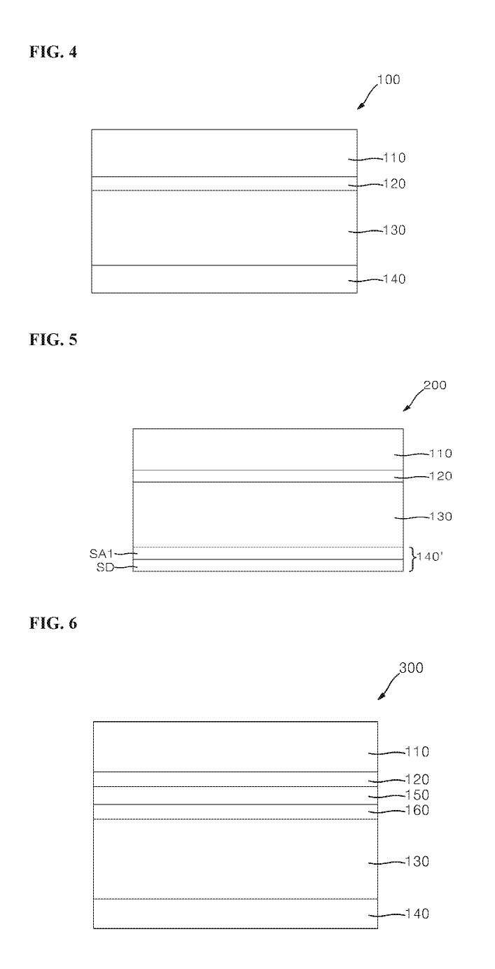

A flexible optical display according to an embodiment of the present invention will be described with reference to FIG. 4. FIG. 4 is a sectional view of a flexible optical display according to an embodiment of the present invention.

Referring to FIG. 4, a flexible optical display 100 according to an embodiment may include a window film 110, a first adhesive sheet 120, an organic light emitting device panel 130, and a second adhesive sheet 140. The second adhesive sheet 140 may include the adhesive sheet according to an embodiment of the present invention. Thus, the flexible optical display 100 can secure good flexural properties and have improved impact resistance by preventing or substantially preventing damage to the organic light emitting device panel 130 due to external impact. The second adhesive sheet 140 is formed on a lower side of the organic light emitting device panel 130 with reference to the window film 110, thereby significantly improving impact resistance of the flexible optical display 100.

The window film 110 is formed at the outermost side of the flexible optical display 100 and can protect the flexible optical display 100. The window film 110 may include any of flexible window films. In one embodiment, the window film 110 may include a base layer and a window coating layer formed on a surface of the base layer. The base layer supports the window film 110, and may include any of flexible films formed of at least one of polyester resins such as polyethylene terephthalate, polyethylene naphthalate, polybutylene terephthalate and polybutylene naphthalate, polycarbonate resins, polyimide resins, polyamide resins, polystyrene resins, and poly(meth)acrylate resins including poly(methyl methacrylate), and the like. The window coating layer is formed on the base layer and at the outermost side of the flexible optical display 100, and may be a flexible coating layer. For example, the window coating layer may include a coating layer formed of a siloxane resin.

The first adhesive sheet 120 is formed between the window film 110 and the organic light emitting device panel 130, thereby bonding the window film 110 to the organic light emitting device panel 130. The first adhesive sheet 120 may be formed of a typical adhesive, for example, an adhesive composition including a (meth)acrylic copolymer as an adhesive resin.

The organic light emitting device panel 130 may drive the flexible optical display 100. In one embodiment, the organic light emitting device panel 130 may include a lower substrate, a thin film transistor, an organic light emitting diode, a planarization layer, a protective layer, and an insulating layer. The organic light emitting device panel 130 directly contacts the second adhesive sheet 140, thereby securing better flexural properties of the display and providing a greater effect of protecting the organic light emitting device panel 130 from external impact. The expression “directly contacting” means that no other intervening layers are present between the organic light emitting device panel 130 and the second adhesive sheet 140.

In FIG. 4, the window film 110 is shown as contacting the organic light emitting device panel 130 via the first adhesive sheet 120. However, the adhesive film or adhesive sheet according to the present invention may be further included between the window film 110 and the organic light emitting device panel 130.

Although not shown in FIG. 4, an optical device, for example, a polarizing plate, a transparent electrode film-containing touch panel, or any adhesive film may be further included between the first adhesive sheet 120 and the organic light emitting device panel 130. A plurality of optical devices may be bonded via typical adhesive films. In addition, although not shown in FIG. 4, a case, a sponge, or the like may be further included on a lower side of the second adhesive sheet 140 via an adhesive film to protect the flexible optical display 100 or to prevent or reduce an impact.

A flexible optical display according to another embodiment of the present invention will be described with reference to FIG. 5. FIG. 5 is a sectional view of a flexible optical display according to another embodiment of the present invention.

Referring to FIG. 5, a flexible optical display 200 according to another embodiment may include a window film 110, a first adhesive sheet 120, an organic light emitting device panel 130, and a second adhesive sheet 140′. The second adhesive sheet 140′ may include the adhesive sheet 30 described above.

Thus, the flexible optical display 200 can secure good flexural properties and have improved impact resistance by preventing or substantially preventing damage to the organic light emitting device panel 130 due to external impact.

A flexible optical display according to another embodiment of the present invention will be described with reference to FIG. 6. FIG. 6 is a sectional view of a flexible optical display according to another embodiment of the present invention.

Referring to FIG. 6, a flexible optical display 300 according to another embodiment may include a window film 110, a first adhesive sheet 120, a touchscreen panel 150, a polarizing plate 160, an organic light emitting device panel 130, and a second adhesive sheet 140. The second adhesive sheet 140 may include the adhesive film according to an embodiment of the invention. The flexible optical display 300 is substantially the same as the flexible optical display 100 described above except that the touchscreen panel 150 and the polarizing plate 160 are further included between the first adhesive sheet 120 and the organic light emitting device panel 130.

The touchscreen panel 150 generates an electrical signal by sensing change in capacitance generated when touched by a human body or a conductor such as a stylus, and a display unit may be driven by such a signal. The touchscreen panel 150 is formed by patterning a flexible conductor, and may include first sensor electrodes and second sensor electrodes formed between the first sensor electrodes and intersecting the first sensor electrodes. The conductor for the touchscreen panel 150 may include metal nanowires, conductive polymers, carbon nanotubes, and/or the like, without being limited thereto. The touchscreen panel 150 may include a base layer and the patterned conductor, and the base layer may include an optically transparent film having or not having a phase difference.

The polarizing plate 160 can realize polarization of internal light or prevent or reduce reflection of external light, thereby realizing a display or improving a contrast ratio of a display. The polarizing plate 160 may include a polarizer alone. Alternatively, the polarizing plate 160 may include a polarizer and a protective film formed on one or both surfaces of the polarizer. Alternatively, the polarizing plate 160 may include a polarizer and a protective coating layer formed on one or both surfaces of the polarizer. Each of the polarizer, the protective film, and the protective coating layer may be typical components known to those skilled in the art.

Although FIG. 6 shows the flexible optical display 300 in which the touchscreen panel 150 is disposed between the first adhesive sheet 120 and the polarizing plate 160, a display, in which the polarizing plate 160 is disposed between the first adhesive sheet 120 and the touchscreen panel 150, falls within the scope of the present invention. In addition, although FIG. 6 shows the flexible optical display 300 including both the touchscreen panel 150 and the polarizing plate 160, a display, in which the polarizing plate 160 is omitted when the base layer of the touchscreen panel 150 is a polarizer, falls within the scope of the present invention. Although not shown in FIG. 6, one or more adhesive films may be included between the touchscreen panel 150, the polarizing plate 160, and the organic light emitting device panel 130. The adhesive films may include typical adhesive films.

Although the flexible optical displays including the adhesive sheet according to embodiments of the present invention have been described above, it should be understood that the adhesive sheet according to embodiments of the present invention may also be used for nonflexible optical displays.

Next, the present invention will be described in further detail with reference to some examples. It should be understood that these examples are provided for illustration only and are not to be construed in any way as limiting the present invention.

### Preparative Example: Preparation of (Meth)Acrylic Copolymer

In a 2 L reactor, a monomer mixture including 364 g of 2-ethylhexyl acrylate, 20 g of hydroxypropyl acrylate, 12 g of acrylic acid, and 4 g of poly(ethylene glycol) methyl ether acrylate (Mw: 480) was placed. 368 g of ethyl acetate was added to the monomer mixture, followed by purging the reactor for 1.5 hours using nitrogen. The reactor was heated to a temperature of 60° C., followed by introducing a solution obtained by adding 0.16 g of azobisisobutyronitrile (AIBN) to 32 g of ethyl acetate to the reactor while a temperature of the monomer mixture was kept constant. After the temperature of the reactor reached 60° C., reaction was maintained for 15 minutes. The monomer mixture was further polymerized for 2 hours, followed by cooling the obtained reaction mixture and diluting the reaction mixture with ethyl acetate, thereby preparing an acrylic copolymer solution including 18 wt % of an acrylic copolymer in terms of solid content. The prepared acrylic copolymer had a weight average molecular weight of 1,900,000 g/mol.

### Example 1

10 parts by weight of the acrylic copolymer of Preparative Example, 1 part by weight of isobornyl acrylate (IBOA) as a monofunctional (meth)acrylic monomer, 1 part by weight of hydroxypropyl acrylate (HPA), and 1.5 parts by weight of pentaerythritol tetraacrylate (PETA) as a polyfunctional (meth)acrylic monomer were mixed, followed by adding 0.5 wt % of Irgacure 184 as an initiator to the mixture based on the total amount of the monofunctional (meth)acrylic monomer and the polyfunctional (meth)acrylic monomer, thereby preparing an adhesive composition. The prepared adhesive composition was coated to a certain thickness onto a corona-treated surface of a polyethylene terephthalate (PET) film (release film, thickness: 50 μm), followed by drying at 110° C. for 5 minutes. Next, an upper side of the coating layer was covered with a 75 μm thick release film, followed by irradiation with UV light (UV dose: 200 mJ/cm²) to perform first curing of the coating layer. A portion of the first cured product, which corresponded to a first region M1, was masked with a mask, followed by performing second curing of the first cured product through UV irradiation (UV dose: 3,000 mJ/cm²) to form second regions M2, thereby manufacturing a 30 μm thick adhesive sheet including the first and second regions M1 and M2. The adhesive sheet was left at room temperature for 12 hours. The first region M1 had a width of 12 mm, and each of the second regions M2, which were formed on both sides of the first region M1, had a width of 74 mm.

### Examples 2 to 7 and Comparative Example 1

Adhesive sheets were manufactured in the same manner as in Example 1 except that the kind and/or amount of the monofunctional (meth)acrylic monomer and the UV doses in first and second curing or irradiation were changed as listed in Table 1.

Composition of each of the adhesive sheets manufactured in the Examples and Comparative Example 1 is shown in Table 1.

TABLE 1

| | | | | | | Polyfunctional | | |
|---|---|---|---|---|---|---|---|---|
| | (Meth)acrylic | Monofunctional | | | | (meth)acrylic | UV dose | |
| | copolymer | (meth)acrylic monomer | | | | monomer | First | Second |
| | (parts by | (parts by weight) | | | | (parts by | irradiation | irradiation |
| | weight) | EEEA | IBOA | HPA | DMAA | weight) | (mJ/cm²) | (mJ/cm²) |
| Example 1 | 10 | — | 1 | 1 | — | 1.5 | 200 | 3000 |
| Example 2 | 10 | — | 1 | 1 | 1 | 1.5 | 200 | 3000 |
| Example 3 | 10 | 1 | 1 | 1 | — | 1.5 | 200 | 3000 |
| Example 4 | 10 | — | 1 | 1 | 2 | 1.5 | 200 | 3000 |
| Example 5 | 10 | — | 1 | 1 | 2 | 2.0 | 200 | 3000 |
| Example 6 | 10 | — | 1 | 1 | 2 | 2.5 | 200 | 3000 |
| Example 7 | 10 | — | 3 | 1 | 1 | 1.5 | 200 | 3000 |
| Comparative | 10 | — | — | — | — | — | 200 | 3000 |
| Example 1 | | | | | | | | |

*EEEA: 2-(2-ethoxyethoxy)ethyl acrylate, IBOA: Isobornyl acrylate, HPA: Hydroxypropyl acrylate, DMAA: N,N-dimethylacrylamide

The adhesive compositions or adhesive sheets of the Examples and Comparative Example 1 were evaluated as to the following properties as listed in Table 2. Results are shown in Table 2.

(1) Storage modulus: Each of the adhesive compositions of the Examples and Comparative Example 1 was coated to a certain thickness onto a release film and dried, followed by performing first UV irradiation under conditions as listed in Table 1, thereby preparing an adhesive film corresponding to the first region M1. In the same manner, each of the adhesive compositions was subjected to first UV irradiation and second UV irradiation under conditions as listed in Table 1, thereby preparing an adhesive film corresponding to the second region M2. The release film was removed, followed by cutting each adhesive film and stacking each adhesive film to a thickness of 600 μm, thereby preparing a square plate-shaped specimen having a size of 10 mm×10 mm (width×length). With the specimen attached to both sides of a central substrate, viscoelasticity was measured on the specimen at a frequency of 1 Hz at a shear strain of 2% (displacement: 16 μm) in a shear strain mode using a dynamic viscoelasticity instrument DMA/SDTA861 (Mettler Co., Ltd.). Measurement was performed while increasing the temperature from −60° C. to 100° C. at a rate of 5° C./min and modulus at each of −20° C. and 25° C. was calculated.

(2) Glass transition temperature: Each of the adhesive layers of the Examples and Comparative Example 1 was subjected to UV curing under conditions as listed in Table 1, thereby obtaining an adhesive film. A specimen of 15 mg of the adhesive film (on 6 mm Al Pan) was prepared and heated to 180° C. at a heating rate of 20° C./min in nitrogen atmosphere (50 mL/min), followed by cooling to −80° C. (first heating condition (1st run)). Next, while the specimen was heated to 180° C. at a heating rate of 20° C./min, the glass transition temperature (Tg) of the specimen was measured.

(3) Impact resistance: An adhesive composition including 10 parts by weight of the (meth)acrylic copolymer of Preparative Example was prepared. The prepared adhesive composition was coated onto a corona-treated surface of a polyethylene terephthalate (PET) film (thickness: 100 μm) and dried, thereby forming a PSA layer (thickness: 50 μm). The other surface of the PSA layer was stacked on one surface of a glass plate (thickness: 0.725 mm). Each of the adhesive sheets of the Examples and Comparative Example 1 was stacked on the other surface of the glass plate, followed by additionally stacking a corona-treated PET film (thickness: 50 μm) on each adhesive sheet, thereby preparing a specimen. The specimen had a sequentially stacked structure of PET film (thickness: 100 μm)/PSA layer (thickness: 50 μm)/glass plate (thickness: 0.725 mm)/adhesive sheet (SA, thickness: 30 μm)/PET film (thickness: 50 μm, modulus at 25° C.: 2,800 MPa, impact dispersion film). The specimen was placed on a stone floor, followed by dropping a steel ball (diameter: 30 mm, weight: 184 g) onto the PET film (thickness: 100 μm) of the specimen, thereby measuring a height causing the glass plate to be broken. A greater height indicates higher impact resistance of the adhesive sheet.

(4) Foldability evaluation: Each of the adhesive films manufactured in the Examples and Comparative Example 1 was placed between a corona-treated polyethylene terephthalate (PET) film (thickness: 125 μm) and a corona-treated PET film (thickness: 50 μm) and attached to the PET films through rollers, followed by aging at room temperature for 12 hours. Next, the resultant was cut to a size of 70 mm×140 mm (width×length), thereby preparing a specimen. With one surface of the 50 μm thick PET film of the specimen secured to a flexibility evaluation instrument (CFT-200, Covotech Co., Ltd.) via an adhesive (4965, Tesa Co., Ltd.), foldability evaluation was performed on the specimen at −20° C. or 60° C. and 93% RH at a folding frequency of 30 cycles/min under the condition of a holding time of 0.1 seconds after each folding such that a radius of curvature became 3 mm. When 1 cycle was defined as an operation of folding the specimen once upon foldability evaluation, the number of cycles, which caused striped pattern, breakage, detachment, or peeling for the first time in a folding portion of the adhesive film, was counted. The adhesive film was rated as 0 when the number of cycles causing such failure for the first time was 100,000 or more, and was rated as X when the number of cycles causing such failure for the first time was less than 100,000.

(5) Peel strength: A PET film (thickness: 50 μm) was subjected to corona treatment twice (total dose: 156) under plasma discharge at a dose of 78 using a corona treatment device. Corona-treated surfaces of the PET films were stacked on both surfaces of each of the adhesive films (thickness: 30 μm) manufactured in the Examples and Comparative Example 1. Next, the stacked body was left at 25° C. for 12 hours, followed by cutting the stacked body to a size of 100 mm×25 mm (length×width), thereby preparing a specimen. Next, the specimen was secured to a universal testing machine (Instron Co., Ltd.). Next, the PET film at one side was kept fixed and the PET film at the other side was pulled at a rate of 50 mm/min in order to measure peel strength of the adhesive film upon T-peeling. Measurement of peel strength was performed at 25° C. Peel strength was measured on each of the first and second regions M1 and M2 of the adhesive film.

TABLE 2

| | | | | | | | | Glass | | | |
|---|---|---|---|---|---|---|---|---|---|---|---|
| | Storage | | Storage | | | Foldability | | transition | | | |
| | modulus | | modulus | | Impact | evaluation | | temperature | | Peel strength | |
| | (−20° C., MPa) | | (25° C., MPa) | | resistance | | 60° C./ | (° C.) | | (gf/in) | |
| | M1 | M2 | M1 | M2 | (cm) | −20° C. | RH93% | M1 | M2 | M1 | M2 |
| Example 1 | 1.09 | 2.4 | 0.20 | 0.27 | 40 | ◯ | ◯ | −36 | −27 | 1299 | 2331 |
| Example 2 | 0.23 | 2.66 | 0.16 | 0.28 | 55 | ◯ | ◯ | −33 | −27 | 1413 | 2527 |
| Example 3 | 1.18 | 1.73 | 0.19 | 0.25 | 30 | ◯ | ◯ | −34 | −27 | 869 | 2428 |
| Example 4 | 1.79 | 2.5 | 0.23 | 0.29 | 30 | ◯ | ◯ | −33 | −28 | 1157 | 2289 |
| Example 5 | 2.23 | 3.68 | 0.32 | 0.45 | 45 | ◯ | ◯ | −32 | −28 | 1240 | 2196 |
| Example 6 | 3.29 | 5.9 | 0.46 | 0.76 | 55 | ◯ | ◯ | −31 | −28 | 1000 | 1966 |
| Example 7 | 3.6 | 11.31 | 0.41 | 0.93 | 45 | ◯ | ◯ | −29 | −22 | 1085 | 2490 |
| Comparative | 0.28 | 0.28 | 0.065 | 0.065 | 25 | ◯ | X | −36 | −36 | 1857 | 1857 |
| Example 1 | | | | | | | | | | | |

As shown in Table 2, the adhesive sheet according to the present invention was composed of a single layer and included the regions M1 and M2 having different moduli, thereby exhibiting good foldability even at high temperature and humidity as well as at low temperature while exhibiting excellent impact resistance. In addition, the adhesive sheet according to the present invention also had excellent peel strength. Conversely, the adhesive sheet of Comparative Example 1, which did not include a monofunctional (meth)acrylic monomer and a polyfunctional (meth)acrylic monomer, did not include regions having different moduli, exhibited poor foldability at high temperature and humidity, and could cause damage to a glass plate due to low impact resistance thereof.

While some embodiments of the present invention have been shown and described herein by way of illustration, it should be understood that various modifications, changes, alterations, and equivalent embodiments can be made by those skilled in the art without departing from the spirit and scope of the present invention.

What is claimed is:

1. An adhesive sheet comprising an adhesive film, the adhesive film comprising: a first region; and a second region coplanar with the first region and having a higher modulus than a modulus of the first region.

2. The adhesive sheet according to claim 1, wherein a modulus ratio of the second region to the first region is from about 1.1 to about 12 at each of −20° C. and 25° C.

3. The adhesive sheet according to claim 2, wherein the first region has a modulus of about 0.1 MPa to about 10 MPa at −20° C.

4. The adhesive sheet according to claim 2, wherein the first region has a modulus of about 0.01 MPa to about 3 MPa at 25° C.

5. The adhesive sheet according to claim 1, wherein a difference in glass transition temperature between the second region and the first region is from about 2° C. to about 50° C.

6. The adhesive sheet according to claim 1, wherein the adhesive film has a thickness of about 200 μm or less.

7. The adhesive sheet according to claim 1, wherein the adhesive film further comprises a third region having a modulus between the modulus of the first region and the modulus of the second region.

8. The adhesive sheet according to claim 1, wherein the adhesive film is formed of an adhesive composition comprising a (meth)acrylic copolymer, a monofunctional (meth)acrylic monomer, a polyfunctional (meth)acrylic monomer, and an initiator.

9. The adhesive sheet according to claim 8, wherein the monofunctional (meth)acrylic monomer has a boiling point of about 200° C. or more.

10. The adhesive sheet according to claim 9, wherein the monofunctional (meth)acrylic monomer comprises at least one of isobornyl (meth)acrylate, 2-ethylhexyl (meth)acrylate, isooctyl (meth)acrylate, lauryl (meth)acrylate, hydroxypropyl (meth)acrylate, hydroxyethyl (meth)acrylate, stearyl (meth)acrylate, 3-trimethoxysilylpropyl (meth)acrylate, diacetone (meth)acrylamide, (meth)acrylamide, 2-(2-ethoxyethoxy)ethyl (meth)acrylate, 2-methoxyethyl (meth)acrylate, tetrahydrofurfuryl (meth)acrylate, ethylene glycol phenyl ether (meth)acrylate, isodecyl (meth)acrylate, 2-(meth)acryloyloxyethyl succinate, isononyl (meth)acrylate, isostearyl (meth)acrylate, caprolactone (meth)acrylate, N,N-dimethyl (meth)acrylamide, octyl (meth)acrylate, octadecyl (meth)acrylate, tert-butyl (meth)acrylate, hydroxybutyl (meth)acrylate, dicyclopentadiene (meth)acrylate, acryloylmorpholine, cyclohexyl methacrylate, and an aromatic (meth)acrylate.

11. The adhesive sheet according to claim 1, wherein the adhesive film is formed of an adhesive composition comprising a monomer mixture comprising a hydroxyl group-containing (meth)acrylate and a comonomer, and organic nanoparticles.

12. The adhesive sheet according to claim 11, wherein the organic nanoparticles have an average particle diameter of about 10 nm to about 400 nm.

13. The adhesive sheet according to claim 11, wherein the organic nanoparticles are core-shell type particles.

14. The adhesive sheet according to claim 13, wherein the core-shell type particles satisfy Equation 1:
Tg(c)<Tg(s),
where Tg (c) is a glass transition temperature (° C.) of a core of the core-shell type particles, and Tg (s) is a glass transition temperature (° C.) of a shell of the core-shell type particles.

15. The adhesive sheet according to claim 11, wherein the organic nanoparticles are present in an amount of about 0.1 parts by weight to about 15 parts by weight relative to 100 parts by weight of the monomer mixture.

16. The adhesive sheet according to claim 1, further comprising: an impact dispersion film on at least one surface of the adhesive film.

17. The adhesive sheet according to claim 16, wherein the impact dispersion film has a modulus of about 100 MPa or more at 25° C.

18. The adhesive sheet according to claim 16, wherein the impact dispersion film has a thickness of less than about 150 μm.

19. An optical display comprising the adhesive sheet according to claim 1.

20. The optical display according to claim 19, further comprising:
a window film; and
an organic light emitting device panel,
wherein the adhesive sheet is on a lower surface of the organic light emitting device panel.
